(19) United States
(12) Patent Application Publication
(10) Pub. No.: US 2018/0217304 A1
(43) Pub. Date: Aug. 2, 2018

(54) Battery-Powered deposition system and process for making reflective coatings

(71) Applicant: David Sheikh, Encinitas, CA (US)

(72) Inventor: David Sheikh, Encinitas, CA (US)

(21) Appl. No.: 15/530,581

(22) Filed: Feb. 1, 2017

(51) Int. Cl. G02B 5/08; C23C 14/56; C03C 17/36; C23C 14/08; C22C 5/06; C23C 14/14; C23C 14/24; C25D 7/08

(52) U.S. Cl. CPC G02B 5/0875; C23C 14/56; C03C 17/3647; C25D 7/08; C22C 5/06; C23C 14/14; C23C 14/24; C23C 14/081

(57) ABSTRACT

A battery powered deposition system and process for applying aluminum, silver, and SiO films (and their derivatives such as aluminum oxide, aluminum nitride and silicon dioxide) especially for making broadband reflective coatings for mirrors. One or more filaments are wetted with a filament wetting material such as aluminum or a silver alloy. In a preferred embodiment filaments are heated quickly to a high temperature with an array of batteries and the filament wetting material is deposited as a reflective coating on the mirror.

### CROSS-REFERENCE TO RELATED APPLICATIONS

This application claims the benefit of provisional application Ser. No. 62/388,546 filed 2016 Feb. 1, 2016.

### FIELD OF THE INVENTION

The present invention relates to a new device and vacuum deposition processes to manufacture broadband reflective coatings for mirrors.

### BACKGROUND OF THE INVENTION

Vacuum deposition refers to a family of processes used to deposit layers of material atom-by-atom or molecule-by-molecule on a solid surface. These processes operate at pressures at below atmospheric pressure (typically between 1×10⁻⁴ torr and 1×10⁻⁷ torr). The deposited layers can range from a thickness of one atom up to several microns. Multiple layers of different materials can be used to form protective coatings or optical interference coatings. Evaporation is a common method of thin-film deposition. Evaporation involves the heating of a source material, which evaporates and condenses on the target object (substrate). Performing the process under vacuum conditions allows vapor particles to travel directly to the substrate, where they condense back to a solid state. The vacuum evaporation process resembles the familiar process by which liquid water appears on the lid of a boiling pot.

Evaporation takes place in a vacuum; therefore, evaporated particles can travel directly to the deposition target without colliding with a significant number of background gas molecules. By contrast, in the boiling pot example, the water vapor makes many collisions with background gases on the way to the lid.

Evaporated atoms that collide with foreign particles may react with them; for instance, if aluminum is deposited in the presence of oxygen, oxygen ions, or nitrogen ions, it will form aluminum oxide, or aluminum nitride. Background gas also reduces the amount of evaporated vapor that reaches the substrate, which makes the deposited thickness difficult to control.

In 1936, the first US company to provide evaporated thin film coatings was established. At this time in American history, few methods to evaporate metal films, or power energetic processes, were available. One of the first methods to create an evaporated coating was termed “hot filament evaporation”. In this method, a tungsten wire (or other high temperature metal wire made from tantalum, molybdenum, or columbium) is first wetted by capillary action, by various pure metals or alloys such as pure aluminum or silver-platinum alloy. When the wet tungsten filament is then heated to a very high temperature using electrical power, the metal on the filament evaporates.

In contrast to filament evaporation (which is a resistive evaporation process), “resistive evaporation” typically refers to melting the evaporating material into a small metal bowl made from a high-temperature metal such as molybdenum, or sublimating a material such as SiO from a small molybdenum box containing a chimney. The evaporating metal in resistive evaporation melts into a liquid and evaporates, or sublimates directly, and the evaporating gas flows in the upward direction if it comes from a liquid bowl, and may disperse in any direction if it is sublimated. Whereas, forces in filament evaporation are governed by surface tension, therefore, the material may be deposited in any direction (up, down, sideways, etc.). This is often an important distinction when coating very heavy mirrors that are more easily placed in the bottom of a vacuum chamber and the coating process therefore, must take place in the downward direction. An evaporation process governed by surface tension may also be beneficial in zero-gravity for coating an optic in the vacuum of outer-space, while in orbit around the earth. The ability to coat an optic in space offers benefit to astronomy since bare aluminum coatings, free of oxygen or organic contamination, are highly reflective into the extreme UV region (EUV) of the electromagnetic spectrum (defined herein as the region between wavelengths of 30-nm to 190-nm).

In the 1960's, 70's, 80's and 90's, other methods to create vacuum coatings were invented such as electron beam evaporation, sputtering, chemical vapor deposition, and others. However, none of these methods is particularly well-suited for coating very large mirrors on earth, or mirrors in space. The inefficiencies of these processes are related to poor compatibility with a zero-gravity environment and/or difficulties in powering the highly energetic processes.

Although it was one of the first methods to produce a thin film vacuum coating, filament evaporation processes are still used today to coat large telescope mirrors at observatories, such as the Palomar Observatory's 5-meter diameter primary mirror. However, because of electrical power limitations (which is often the case on the top of large mountains where observatories are typically located, or in the vacuum of outer space in the case of a space-based observatory on-orbit), relatively few filament evaporation sources may be powered at the same time. Using too few sources limits the evaporation rate, which the metal film may grow on the substrate, and it limits how flat and uniform the film will be deposited on the mirror substrate. A slow growing aluminum film results in poor UV reflectance, and non-uniformity of the coating results in wavefront error for the telescope system.

### Systems and Processes for Coating Mirrors in Space

### Astronomers Study Extreme UV Wavelengths to Reveal the Composition and Age of Stars

Aluminum films manufactured in the vacuum of space may increase the broadband reflectance response of a space telescope operating in the EUV region of the spectrum, by eliminating absorbing metal-fluorides and metal-oxides, which significantly reduce aluminum's reflectance below 160-nm. These fluoride and oxide materials are either added (in the case of fluorides) to protect the aluminum reflector from oxidation, or form naturally (oxides) when the bare aluminum leaves the vacuum coating chamber and is exposed to the earth's atmosphere.

### NASA's Aluminum Coatings Made on Earth

### For Use in Space for FUV Telescopes Operating Between 90-nm and 190-nm

Aluminum is the most reflective metal in the far ultraviolet (FUV) region of the electromagnetic spectrum (defined as wavelengths of about 90-nm to about 190-nm); however, a thin aluminum-oxide film, about 2-nm to 4-nm thick forms when bare aluminum is exposed to the atmosphere. The thin aluminum oxide film is highly absorbing over most of the FUV region. To prevent the formation of aluminum oxide, a thin metal fluoride layer, such as MgF₂, LiF, or AlF₃, is typically applied immediately onto a freshly-coated aluminum film.

An aluminum reflector over-coated with a metal-fluoride such as LiF or MgF₂ is the current standard for wide-band reflective, space telescope systems operating down to 90-nm. NASA's HUBBLE, FUSE, GALAX, TTI, COSTAR, STIS, and ACS, all employed these coating systems with success, however, the performance of these mirrors in the FUV spectral region is less than the theoretical value and the mirrors often degrade during ground storage and in space. HUBBLE was the only very large astronomy telescope (2.4-m primary mirror) coated with an Al/MgF2 system, and its performance in the FUV was considerably less than the theoretical value. NASA experts believe that poor FUV reflectance performance of primary mirrors (like the Hubble Space Telescope) is in part due to insufficient coating rates during the aluminum deposition process (ref., Kunjithapatham Balasubramanian, et. Al “Aluminum mirror coatings for UVOIR telescope optics including the far UV”. Proc. SPIE 9602, UV/Optical/IR Space Telescopes and Instruments: Innovative Technologies and Concepts VII, 960201 (Sep. 22, 2015); doi:10.1117/12.2188981.) The teachings of these papers are incorporated herein by reference.

Coatings for future FUVOIR space-based observatories require improvement in the optical coating performance, as well as, a practical means to apply them to large mirror structures. It should be noted that in this case, it is a new coating process and not a new coating recipe, which will be critical for meeting future FUV-broadband coating requirements for future space telescopes.

In 2012, NASA researchers published a paper describing a 3-step coating process to produce FUV reflective coatings over 90% reflective in specific FUV wavelength regions. The GSFC 3-step process for applying a metal fluoride protected aluminum coating for FUV mirrors (M. A. Quijada, S. et. Al, “Enhanced MgF2 and LiF Over-coated Al Mirrors for FUV Space Astronomy,” Proc. SPIE 8450 (2012)). The GSFC 3-step process may be summarized as follows:
1. Apply aluminum coating using multiple resistive evaporation sources at >125 A/sec in very dry, high-vacuum conditions
2. Apply a thin 2-5 nm layer of metal-fluoride (LiF, AlF3, or MgF2 at room temperature immediately upon completion of the aluminum layer to quickly arrest oxidation of the aluminum film.
3. Heat the substrate to ˜200° C. and apply additional metal-fluoride at higher temperature to produce a high-quality crystalline layer for good protection in humid ground-storage environments.

GSFC currently arranges eighteen filament evaporation sources around the perimeter of a circular coating area to achieve an aluminum coating rate of 125 angstroms/second, and this arrangement reaches its limits at about 1-meter because the required distance from the evaporation source to the substrate becomes too large as the substrate size increases. Furthermore, with a circular arrangement, the size of the chamber required is much larger than the size of the optic that may be uniformly coated. For example, GSFC currently uses a two-meter diameter vacuum to coat a 1-meter substrate with a coating uniformity of about +/−10%.

To date, NASA's “3-step coating” has not been demonstrated on mirror substrates greater than 1-meter and scaling the coating process to larger mirror sizes is challenging for the following reasons:
1. The number of evaporation filament sources required to coat a large optic becomes very large (hundreds) and the power requirements are excessive (tens of thousands of amps).
2. Out-gassing from power cables may contaminate aluminum coatings
3. Heating an optic to 200° C. for metal-fluoride deposition is problematic for polymer-bonded mirror assemblies.

The NASA 3-step coating process for FUV coatings represents the current state-of-the-art. What is needed is a better system and process for applying the aluminum portion of the NASA's 3-step coating process.

### Coating Large Mirrors with Protected Silver for Ground-Based Observatories

The current state-of-the-art protected silver coating for large ground-based telescope mirrors is based on a patented process (Wolfe, Jesse D., and Norman L. Thomas. “Durable silver coating for mirrors.” U.S. Pat. No. 6,078,425. 20 Jun. 2000, incorporated herein by reference.). This process is based on sputtered coatings and is currently being used by the Twin Gemini telescopes (8-meter primary mirrors) located in Hawaii. The two main drawbacks for this coating recipe and process are; 1) poor coating uniformity using movable sputter targets, which leads to significant wavefront error for UV-visible telescopes, 2) poor UV and blue reflectance because of the use of nickel-chromium-nitride and silicon nitride in the protective coating recipe, which absorbs significant energy in these bands.

What is needed is a system, process, and new coating recipe for applying protected silver coatings to large, heavy mirrors, in a downward direction, with improved reflectivity and improved coating uniformity. In the forthcoming paragraphs, we describe in detail such a system, process, and recipe.

### SUMMARY OF THE INVENTION

The present invention provides a battery powered deposition system and process for applying aluminum and silver films and their derivatives such as aluminum oxide, aluminum nitride and silver oxide, especially for making broadband reflective coatings for mirrors.

For example, a protected silver coating process based on many filament evaporation sources powered by batteries allows the coating to be deposited in any direction, including a downward direction, which is a necessity when coating very large, heavy mirrors, that may not be readily manipulated and hung upside down (sputtering is currently used at Gemini because it may be applied in the downward direction, and electron beam evaporation occurs in the upward direction because of the molten metal materials within the evaporation crucible). However, filament evaporation severely limits the choices of materials that may be evaporated. This limits the protective coating recipes that may be devised to prevent degradation of the silver reflector over time due to tarnishing. Applicant has shown through experiment and test that a durable silver coating may be produced by protecting the silver with alternating layers of aluminum nitride and aluminum oxide made by a filament evaporation process. Therefore, a complete silver coating can be created using only aluminum and silver in embodiments of the present invention with this filament evaporation process. In this case to produce the oxides and nitrides a small amount of oxygen or nitrogen is added to the vacuum chamber.

Applicant has also devised a battery-powered deposition (BPD) process for making broadband reflective coatings that could make coating in space relatively simple. The process uses an array of hot filaments powered by batteries, which are contained in small pressurized vessels within a vacuum chamber (or in the vacuum of space). The filaments are pre-coated with the evaporation material and the device is simply “lit up” like a 700-watt, handheld flashlight. Applicant's prototype BPD unit is relatively large, but the device could easily be miniaturized into something the size of a medicine bottle. As battery technology continues to improve over the next decade and energy densities increase, the evaporation device could be reduced to the size of a wrist watch.

Carrying low-voltage and high current over significant distances to many small evaporation sources would require heavy copper cables and large powers supplies, and is therefore less practical for coating in space. The use of batteries placed near the individual evaporation sources solves this problem. Also, if the reflective coatings degrade over time from outgassing of the spacecraft, they could be over-coated and refreshed periodically. A small mirror could be coated by a single evaporation source, or many evaporators could be fabricated into an array, to coat large mirrors. For large mirrors, the battery canisters may be tied together into an array with control wires.

### Small Prototype System and Process

Applicant has built and tested a single battery-powered deposition unit in accordance with features of the present invention. This embodiment utilizes a single battery powered tungsten filament wet with aluminum to coat a relatively small area (˜0.5-meters in diameter) within a vacuum chamber, and a map generated representing the coating thickness as a function of position within this coated area. The measured coating thickness distribution was used to create a mathematical model representing the shape of the evaporation plume. A computer modeling program was developed, which incorporates the plume shape data and allows multiple plumes arranged in hexagonal pattern to be combined. The output of the model gives detailed information regarding the resulting coating thickness over a large area for combined plumes, the total thickness of coating deposit, the coating deposition rate for combined plumes, and the coating uniformity as a function of plume spacing. A detailed description of this embodiment and the results of the tests of the coated mirror are described below. The evaporation unit was comprised of a stainless-steel tube with sealable endcaps suitable for placement in a vacuum chamber, two 26650 LiFePO₄ batteries, an electromagnetic relay to turn the unit on and off from outside the vacuum chamber via a vacuum feed-through, and a tungsten coil filament (RD-Mathis part# B12B-.04W) pre-melted with aluminum.

In Applicant's demonstration experiment, he constructed the coating system and turned on the two batteries at full power and observed the deposition process. The completed deposition unit was placed inside a 1.2-meter vacuum coating chamber and below an un-coated mirror substrate. A quartz crystal monitor was placed 2-inches to the side of the mirror substrate. The deposition unit was turned on by activating the relay and aluminum deposition began a few seconds later. The two 4-Amp-Hr, 3.7V LiFePO₄ batteries were placed in series and discharged in about 60-seconds. The voltage at the filament was measured at 4.5-volts. About 2,400-angstroms of aluminum was deposited on the mirror substrate at 40 A/second. A temperature sticker applied to the side of the battery indicated that the battery reached 78° C. during the experiment. A residual gas analyzer (RGA) was used to record background partial pressures to demonstrate the pressurized vessel containing the batteries did not leak into the vacuum chamber during the experiment. For example, in a preferred embodiment for coating a future six meter NASA space telescope mirror, based on modeling, the required coating process would use over 2,000 battery-powered filaments arranged in a hexagonal pattern to achieve a coating deposition rate of 133 angstroms/second with a coating uniformity of +/−3.2%, as well as, a coating that meets the reflectance and wavefront error requirements currently anticipated by NASA for a future Flagship mission.

Part numbers and suppliers for the off-the-shelf parts of the prototype battery-powered deposition unit (BPD unit), which was built and tested, are specified below:

### Prototype Battery-Powered Deposition Unit (Parts List and Supplier)

Part No: QF50-200-C

Description: Clamp, Aluminum, QF50, Cast 2″

Vendor: Kurt J. Lesker

Vendor Address: 3983 1^{st} Street, Livermore, Calif. 94551

Part No: QF50-200-SRB

Description: Centering ring, SS, QF50, BUNA

Vendor: Kurt J. Lesker

Vendor Address: 3983 1^{st} Street, Livermore, Calif. 94551

Part No: QF50-200-BB

Description: Flange, Blank, Brass, QF50

Vendor: Kurt J. Lesker

Vendor Address: 3983 1^{st} Street, Livermore, Calif. 94551

Part No: QF50-200-NL

Description: Nipple, SS, Long, QF50 FLGS, 2″OD Tube, “A”—12.60

Vendor: Kurt J. Lesker

Vendor Address: 3983 1^{st} Street, Livermore, Calif. 94551

Part No: Per customer drawing

Description: Filament wire mount

Vendor: Clint Precision Mfg.

Vendor Address: 7665 Formula Place Ste A, San Diego, Calif. 92121

Part No: 26650 LiPO4 Batteries, 90 Amp discharge (or equivalent)

Description: Batteries

Vendor: Drone Charge Up

Vendor Locations: Magnolia Street, Fountain Valley, Calif. 92708

Part No: Aluminum wire, 1.5-mm

Description: Aluminum wire, 1.5-mm diameter, 99.999% purity

Vendor: Laurand Associates, Inc.

Vendor Address: 11 Grace Avenue, Ste 405, Great Neck, N.Y. 11021

Part No: B12B-0.40 W

Description: Tungsten filament, 5 Coil

Vendor: RD Mathis

Vendor Address: 2840 Gundry Ave, Signal Hill, Calif. 90755

### Energy Control

When the deposition unit is energized, it is important to control the rate of energy supplied to the filament. This allows the deposition material contained on the filament, to be warmed to the melting point, and then heated more rapidly by turning up the current to the filament. This process prevents the filament from being over-energized when it is cold and the resistance in the tungsten filament is low. Applicant uses a programmable circuit to accomplish the controlled release of electrical power to the filament. It is also important that the evaporation process be stopped before all the aluminum is removed from the tungsten filament, to minimize tungsten (or tantalum, platinum, columbium) contamination on the mirror coating. A mechanical shutter is our preferred method to abruptly halt the deposition of material on the mirror substrate. Stopping the process abruptly with a shutter also prevents low rate material from reaching the substrate (if power is cut, for example).

### Batteries

The deposition filament may be used several times, limited by the amount of available coating material present on the filament. Some embrittlement of the tungsten filament occurs over time, limiting its useful life and the filament must be replaced from time-to-time. The battery chemistry for the prototype device was LiFePO4, and the batteries used were relatively small and rechargeable, however, many modern battery chemistries are suitable for use with the deposition unit. It may be noted that battery improvements in the past decade have directly lead to the practicality of the said invention, although larger, less efficient batteries could also be used with success.

### BRIEF DESCRIPTION OF THE DRAWINGS

FIG. 1 is a sketch of a single battery-powered deposition (BPD) unit.

FIG. 2A shows a concept for a Cassegrain-Telescope integrated with a hexagonal battery-powered coating system in a coating position.

FIG. 2B shows a concept for a Cassegrain-Telescope integrated with a hexagonal battery-powered coating system in an observation position.

FIG. 3 is a sketch of a single BPD unit with a mechanical shutter.

### DETAILED DESCRIPTION OF PREFERRED EMBODIMENTS

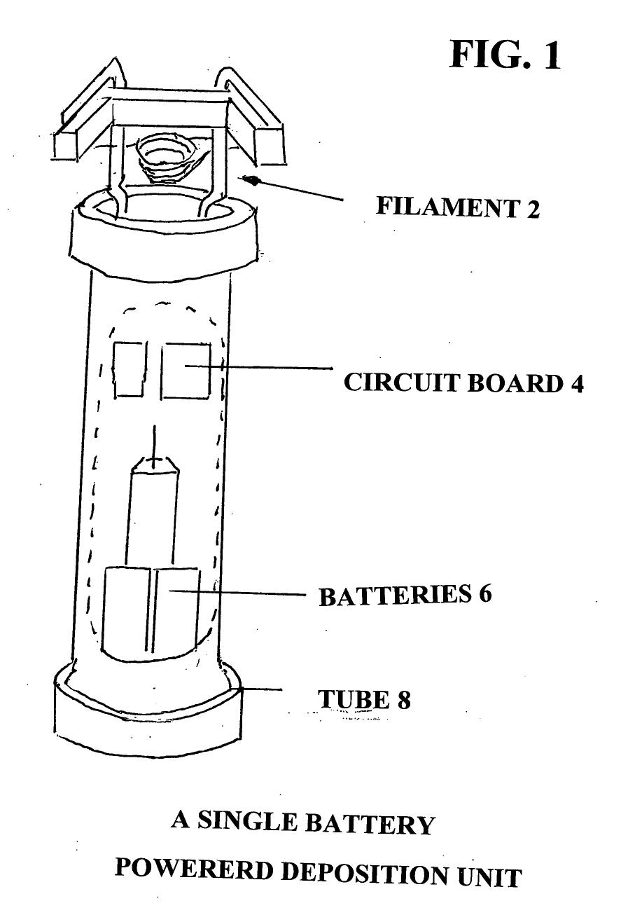

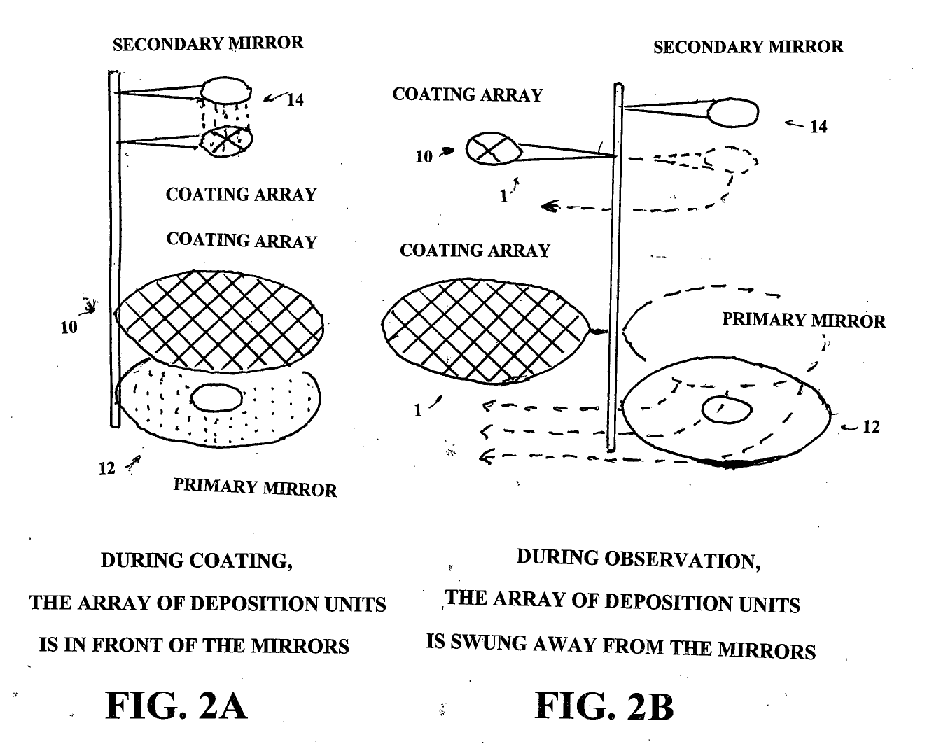

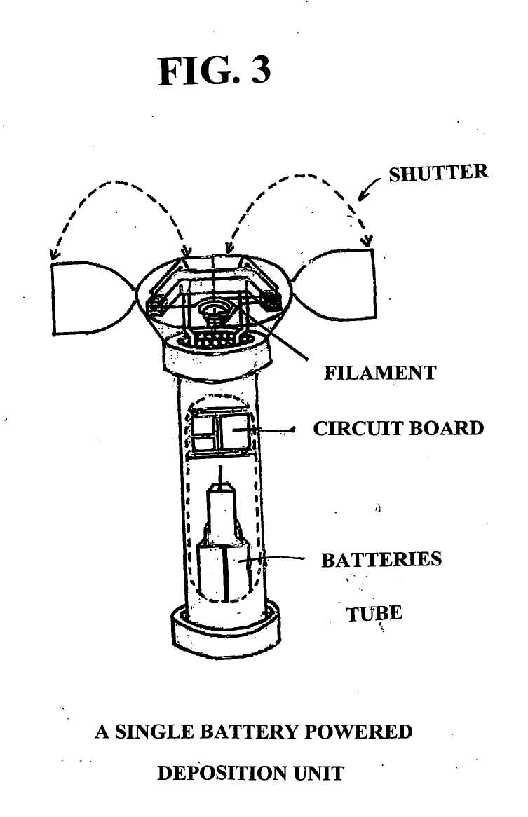

FIG. 1 is a sketch of a single battery-powered deposition (BPD) unit. The unit 1 includes a filament 2 and circuit board 4 and two batteries 6 both contained in leak-proof tube 8. FIGS. 2A and 2B show individual BPD units 1 arranged in a hexagonal pattern 10 In these two drawings, a Cassegrain-Telescope with a primary mirror 12 and a secondary mirror 14 integrated with the battery-powered coating system. In this integration concept, a disc-shaped array of evaporators swings in front of the mirror for coating, and then swings out of the way for observations as shown in FIGS. 2A and 2B. More complicated telescopes with additional small mirror bounces and gratings can be accommodated with single BPD units, which also swing in front of their optics. The optical design of the system must, of course, provide physical space for these devices and motions.

As describe in detail below with embodiments of the present invention mirrors can be coated in space with important advantages. One other benefit to coating in space is the possibility of removing dust contamination prior to coating. If dust contamination could be removed, a much less scattering optical surface could be created and maintained. Ultra-low scattering mirrors are ideal for extrasolar planet coronagraphy. Significant improvements in system performance may be realized, even if only the smaller mirrors near the image plane are cleaned just prior to coating in space.

The present invention provides substantial improvements in reflectance and coating uniformity compared to the state-of-the-art, particularly for very large mirrors several meters in diameter. However, the process may be applied to any size mirrors from mirrors as small as a few centimeters (such a 5-cm) to mirrors as large as or larger than eight meters. The present invention utilizes a new battery-powered deposition (BPD) device to apply the coating layer or layers. In preferred embodiments, the reflective layer may be bare aluminum coated in space, an aluminum reflector protected by metal-fluorides and manufactured in a vacuum chamber on earth for subsequent use in space, or a protected and enhanced silver reflector manufactured at a large observatory on a mountaintop on earth. The new processes use one or more evaporation filaments powered by lithium batteries contained in small pressurized vessels within a vacuum chamber, or in the vacuum of space. For large mirrors, many evaporation filaments are desirable to achieve high evaporation rates (for improved aluminum coatings) and for improved coating uniformity, which results in improved waverfront error and improved telescope system performance.

### Three Preferred Embodiments

### Battery-Powered Coating Process for Mirrors Coated in Space

Recent developments in battery technology allow small lithium batteries to rapidly discharge large amounts of energy. It is therefore conceivable to power an array of resistive evaporation filaments in a space environment, using a reasonable mass of batteries and other hardware. A battery-powered process, therefore offers the possibility of eliminating the need for a protective metal-fluoride over-coat altogether, which could yield reflectance values approaching 90% in the 90-190-nm region, and substantial reflectance in the EUV region from 30-90-nm. This improvement would be of great benefit to astrophysics. It is a primary objective of the invention described herein, to create a process that delivers exceptionally high deposition rates over very large coating areas by using batteries to power a large array of individual evaporation filaments.

Another possibility is the ability to change the coating from aluminum to silver once in orbit. For example, aluminum coatings have good FUV and EUV performance for investigating star formation, but are highly polarizing, which is not optimum for looking at reflected light from extra-solar planets. Silver coatings could be applied to mirrors in space using the battery-driven process to create a less polarizing coating for observing reflected energy from extra-solar planets. The ability to change the coating from aluminum to silver, once the telescope is in orbit using a battery-powered coating process, would allow both scientific objectives to be realized with a single large telescope.

A first example of a preferred embodiment of the present invention is the coating of a future 6-meter primary mirror in the vacuum of space, such as NASA's proposed HABEX space telescope. The main advantage of coating a mirror in space is the bare aluminum coating will reflect energy down to 30-nm wavelengths, whereas an aluminum coating made on earth must be protected with a fluoride-based coating to prevent oxidation. Protected aluminum coatings are limited to a minimum wavelength of about 90-nm because the fluoride over-coats absorb almost all energy below 90-nm. Based on our mathematical model of a single battery-powered deposition device, a six-meter diameter primary mirror (such as a mirror proposed for NASA's HABEX), would require 81 simultaneously energized evaporation filaments per square meter (or 2,289 total for a 6-meter diameter mirror), to yield a coating uniformity of 6.4% peak-to-valley (PTV). This level of uniformity is within the anticipated wavefront error budget of 5-nm RMS (˜25-nm PTV) for the telescope's primary mirror. The current-state-of-the-art coating technology does not provide a means to rapidly apply an aluminum coating with sufficient speed and precision to meet NASA's current requirements for future telescopes, but Applicant's proposed battery-powered deposition process will meet these requirements. The predicted evaporation rate for this coating process is 133 A/sec, which has been shown in previous research, to be adequate to create high reflectance and low scatter aluminum coatings in the extreme ultraviolet portion of the electromagnetic spectrum (EUV). In a space-based coating operation, the other smaller mirrors in the telescope system must also be coated in space (to use bare, unprotected aluminum with the highest EUV reflectance), with similar processing conditions, and to meet similar reflectance and wavefront requirements.

### Battery-Powered Coating Process Applied in Vacuum Chamber for Use in Space

A second example of a preferred embodiment of the present invention is the BPD coating of a large space telescope mirror (like the HABEX example in the first preferred embodiment) except the large primary mirror is coated in a vacuum chamber on earth, for use later in space. In this case, the battery powered filament evaporation process is again used to obtain the high evaporation rates needed for high reflectance in the FUV portion of the electromagnetic spectrum (between 90-nm and 190-nm), as well as, to achieve an approximately flat coating, which meets the anticipated wavefront requirements of a large, future space telescope. However, in this case, the aluminum-coated mirror is protected from oxidation using additional layers of fluoride materials such as aluminum fluoride, magnesium fluoride, or lithium fluoride and these protection schemes were developed by at NASA-JPL and NASA-Goddard Spaceflight Center (GSFC) (ref., (1) Kunjithapatham Balasubramanian, et. Al “Aluminum mirror coatings for UVOIR telescope optics including the far UV”. Proc. SPIE 9602, UV/Optical/IR Space Telescopes and Instruments: Innovative Technologies and Concepts VII, 960201 (Sep. 22, 2015); doi:10.1117/12.2188981. (2) M. A. Quijada, et. Al., “Enhanced far-ultraviolet reflectance of MgF2 and LiF over-coated mirrors”, Proc. SPIE Vol 9144 9144G-1 (2014).)

The protective fluoride layers in the NASA recipes need not be deposited with the filament evaporation process and may be deposited with a conventional resistive evaporation process, by electron beam evaporation, or by sputtering. The protective fluoride layers are typically applied very thin (2-nm to 20-nm thick) and have little impact on wavefront error for the telescope system.

### Battery-Powered Silver Coating Process for Very Large Telescope Mirrors

A third example of a preferred embodiment of the present invention is the coating with the battery-powered deposition method of a large ground-based telescope primary mirror with a protected silver coating. An example is the future Giant Magellan Telescope (GMT) currently under design and construction in Chile. This telescope uses seven, 8-meter diameter mirror segments. Currently there is no existing coating technology to produce protected silver coatings for very large ground-based astronomy mirrors that have sufficient reflectance in the visible and UV portions of the magnetic spectrum, like those specified by GMT.

In this example of a preferred embodiment, hundreds of silver-coated tungsten filaments and hundreds of aluminum-coated tungsten filaments would be energized in groups, with battery power, sometimes in the presence of ionized oxygen or nitrogen species supplied by multiple End-Hall ion sources, to create a multi-layer protected silver coating comprised of protective alternating aluminum nitride and aluminum oxide layers placed on top of a silver reflector. Protective silver coating recipes using aluminum oxide and aluminum nitride as protective layers, are described in previous patents (Adams, Harvey N., “Protective coating for surfaces of silver and mirror fabrication.” U.S. Pat. No. 3,687,713. 29 Aug. 1972; Wolfe, Jesse D., “Durable low-emissivity solar control thin film coating”, U.S. Pat. No. 5,377,045, 27 Dec. 1994). For earth-based telescopes astronomers are not concerned with very short UV wavelengths since these wavelengths are almost completely absorbed in the earth's atmosphere. Also In a previous patent (W. H. Colbert, 1946, “Method or Process of Evaporating Metals”, U.S. Pat. No. 2,413,604) small amounts of alloying metals such as platinum, cobalt or nickel (1% to 10%) were added to a silver melt to make a tungsten evaporation filaments receptive to the molten silver, allowing wetting of the tungsten filament.

The new protective silver design also utilizes optical interference effects to increase the reflectance in the ultraviolet portion of the spectrum between 320-nm and 400-nm. The coating design may be constructed using only battery-powered filament evaporation processes as follows, with layer thickness adjusted to meet durability and reflectance requirements:

### Layer 0. Substrate

Layer 1. Aluminum oxide (adhesion layer)
Layer 2. Silver (reflector)
Layer 3. Aluminum nitride (protection/UV-blue enhancement)
Layer 4. Aluminum oxide (protection/UV-blue enhancement)
Layer 5. Aluminum nitride (protection/UV-blue enhancement)
Layer 6. Aluminum oxide ((protection/UV-blue enhancement)

Additional preferred embodiments of the present invention are described below:

### Battery-Powered Filaments for Radiant Heating

Large mirror assemblies often utilize bonded attachments, which have upper temperature limits of less than 100 C. Since it is desirable to coat mirror assemblies rather than bare mirror substrates, a relatively low-temperature coating process is usually desirable. One solution to this dilemma is to quickly heat only the surface of the mirror substrate, rather than the entire mirror assembly. Using many battery-powered heating filaments the mirror substrate may be heated if necessary for subsequent thin film coating deposition.

### Battery-powered Filaments for Reduced Outgassing

Using batteries to power the deposition process allows the power supply (the battery) to be near the evaporation filament, eliminating the need for large copper cables to carry the low-voltage, high current over large distances (from the transformer outside the chamber, to the filaments at various positions inside the chamber). Reduced electrical wiring means less outgassing when the system is energized, hence better quality aluminum. For example, the tungsten filament used in our demonstration experiment required about 4-volts and 250-amps to power it. To coat a large mirror 6-meters in diameter, thousands of simultaneously fired filaments may be required releasing over a megawatt of power for a few seconds! This power requirement is burdensome to achieve in space, or on earth using conventional AC line power, however, this electrical discharge is quite easy with modern lithium batteries (which have greatly improved over the last decade).

### Variations

Persons skilled in mirror coating art will recognize that there are many variations and additions possible to the systems and processes described in detail above. For example; a sublimation box could be powered by batteries with a similar construction to a battery-powered filament device, to create SiO or ZnS films. These dielectric films may be used for protective layer materials or optical materials. The vapor from a sublimation box may be emitted in any direction, like filament evaporation. Oxygen or oxygen ions may be added to SiO films to create SiO2 films. A second example; aluminum coatings applied to large ground-based telescope mirrors often suffer from slightly lower reflectance near the atmospheric UV wavelengths of 320-400-nm and reflectance may be improved by adding more filament evaporation sources to the system. A third example; other elements, compounds, or alloys may wet with various filaments comprised of tungsten, tantalum, platinum, or columbium, or their alloys, and be used in a battery-powered filament evaporation process.

Therefore, the scope of the present invention should be determined by the appended claims and their equivalence.

What is claimed is:

1. A method of producing coatings by vapor deposition from at least one filament fabricated from a filament material selected from a group of filament materials consisting of tungsten, tantalum, molybdenum and columbium comprising the steps of:
A) wetting the filament with a filament wetting material selected from a group filament wetting materials consisting of aluminum and a silver alloy;
B) depositing at least a portion of the filament wetting material on a substrate positioned in a vacuum chamber or outer space by heating the filament to a temperature in excess of the boiling point or the sublimation point of the wetting material with electric energy supplied by at least one battery contained in a leak-proof container containing the battery and a circuit board programmed to control energy applied to the filament so as to control the rate of deposition of filament wetting material on the substrate.

2. The method as in claim 1 wherein a mechanical shutter is provided with respect to each of the at least one filament and adapted to precisely start and stop the deposition of the filament wetting material.

3. The method as in claim 1 wherein the at least one wherein the at least one filament and at least one battery are an array of filaments and batteries each contained in a leak proof vacuum compatible container, together defining an array of vapor deposit units.

4. The method as in claim 3 wherein the array vapor deposit units is a hexagonal array.

5. The method as in claim 4 wherein the hexagonal array of vapor deposit units comprises a plurality of vapor deposit units chosen to assure a desired coating uniformity.

6. The method as in claim 3 wherein the substrate is a mirror.

7. The method as in claim 6 wherein the mirror has a diameter of at least one meter.

8. The method as in claim 6 wherein the mirror has a diameter of at least eight meters.

9. The method as in claim 8 wherein the deposition takes place in outer space.

10. The method as in claim 8 wherein the deposition takes place in a vacuum chamber.

11. A system for producing thin film coatings on a substrate by vapor deposition comprising:
A) At least one filament wetted with a filament wetting material selected from a group filament wetting materials consisting of aluminum and a silver alloy;
B) a substrate positioned in a vacuum chamber or outer space; and
C) at least one battery contained in a leak-proof vacuum compatible container containing the battery and a circuit board programmed to control energy applied to the filament by the battery so as to heat the filament to a temperature in excess of the boiling point or the sublimation point of the wetting material in order to produce a thin film not exceeding 5,000 angstroms on the substrate with a controlled deposition rate.

12. The system as in claim 11 and further comprising mechanical shutter for each of the filaments adapted to precisely start and stop the deposition of the filament wetting material.

13. The system as in claim 11 wherein the at least one filament and at least one battery are an array of filaments and batteries each contained in a leak proof vacuum compatible container, together defining an array of vapor deposit units.

14. The system as in claim 13 wherein the array of vapor deposit units is a hexagonal array.

15. The system as in claim 14 wherein the hexagonal array of filaments comprises a number of vapor deposit units is chosen to assure a desired coating uniformity.

16. The system as in claim 11 wherein the substrate is a mirror.

17. The system as in claim 14 wherein the mirror has a diameter of at least one meter.

18. The system as in claim 15 wherein the mirror has a diameter of at least eight meters.

19. The system as in claim 14 wherein the deposition takes place in outer space.

20. The system as in claim 14 wherein the deposition takes place in a vacuum chamber.

21. The system as in claim 14 wherein the mirror is a part of a telescope defining an optical path and the array of filaments are configured so as to be moved out of the optical path when the telescope is used for observation.

22. The system as in claim 15 wherein the coating is an aluminum coating adapted for reflecting far ultraviolet light in a frequency range of 30 nm to 2500 nm with an average reflectance greater than 90 percent over most of the band

23. The process as in claim 6 wherein the mirror is a part of a telescope defining an optical path and the array of filaments are configured so as to be moved out of the optical path when the telescope is used for observation.

24. The process as in claim 6 wherein the coating is a silver alloy coating adapted for reflecting UV to visible light in a frequency range of 310 nm to 20 microns with an average reflectance greater than 90 percent.

25. The process as in claim 1 wherein the silver alloy comprises trace impurities chosen to permit the silver alloy to wet the filament material.

26. The process as in claim 1 wherein the filament wetting material is a silver alloy and the process vacuum chamber is infiltrated with sufficient nitrogen or oxygen to permit deposition of one or more layers of aluminum nitride or aluminum oxide.
